(19) United States
(12) Patent Application Publication
(10) Pub. No.: US 2001/0023107 A1
(43) Pub. Date: Sep. 20, 2001

(54) METHOD FOR FABRICATING A HYBRID ISOLATION STRUCTURE

(76) Inventors: GARY HONG, HSIN-CHU (TW); WENCHI TING, TAIPEI CITY (TW)

Correspondence Address: JIAWEI HUANG, J C PATENT INC, 1340 REYNOLDS AVENUE, SUITE 114, IRVINE, CA, 92614

(21) Appl. No.: 09/299,719

(22) Filed: Apr. 26, 1999

(30) Foreign Application Priority Data
Dec. 3, 1998 (TW) 87120060

(51) Int. Cl. H01L 21/336

(52) U.S. Cl. 438/294

(57) ABSTRACT

Alternative methods are provided for fabricating a hybrid isolation structure on a semiconductor substrate, wherein, the hybrid isolation structure includes a shallow trench isolation (STI) and a field oxide isolation formed by local oxidation of silicon (LOCOS). In detail, the STI is formed within a device region that is operated at a low working voltage, a logic device region, to efficiently enhance the device density. On the other hand, the LOCOS isolation is formed within a device region that is operated at a high working voltage, a memory device region, to ensure the reliability and performance of the devices.

### CROSS-REFERENCE TO RELATED APPLICATION

This application claims the priority benefit of Taiwan application serial no. 87120060 filed Dec. 3, 1998, the full disclosure of which is incorporated herein by reference.

### BACKGROUND OF THE INVENTION

1. Field of the Invention

This invention relates to a method for fabricating a semiconductor device, and more particularly, to a method for fabricating a hybrid isolation structure including a field oxide and a shallow trench isolation (STI). The field oxide is formed by local oxidation of silicon (LOCOS) and is located within a memory device area, while the STI is formed within a logic device area.

2. Description of Related Art

A field oxide layer formed by a semiconductor fabrication LOCOS method is conventionally used as the isolation between active regions on a semiconductor substrate. Since the LOCOS isolation normally occupies a relatively large surface area of a semiconductor substrate, it has been replaced, in some highly integrated semiconductor devices, by a recently developed STI to enhance device density and performance. However, since STI performance is still not very stable when used in some situations, such as isolating active regions that have a high working voltage, the STI has not yet been fully employed to enhance semiconductor device integration and performance.

When the STI is used to isolate active regions that carry a high working voltage, over 5 volts, the performance and reliability of the device are degraded by effects such as leakage current and unwanted substrate current. As shown in FIG. 1, as a result of forming an STI 12 in a semiconductor substrate 10 to isolate two active regions, a dished area 16 is usually formed on the edge of active region. If a follow-up process for forming a gate oxide 14 is performed on the substrate 10, an abnormally thin portion of gate oxide 14 is obtained over the dished area 16. Problems like leakage current and unwanted substrate current occur due to the abnormally thin gate oxide layer 14 that degrade the reliability and performance of the device.

### SUMMARY OF THE INVENTION

It is therefore an objective of the present invention to provide a hybrid isolation structure that efficiently enhances the device density of a device region operated at a low voltage.

It is another objective of the present invention to provide a hybrid isolation structure that ensures the reliability of a device region operated at a relatively high voltage.

In accordance with the foregoing and other objectives of the present invention, the invention provides a method for fabricating a hybrid isolation structure on a semiconductor substrate, wherein the hybrid isolation structure includes a shallow trench isolation (STI) and a field oxide isolation formed by local oxidation of silicon (LOCOS). In detail, the STI is formed within a device region that is operated at a low working voltage, a logic device region, to efficiently enhance the device density. On the other hand, the LOCOS isolation is formed within a device region that is operated at a high working voltage, a memory device region to ensure the reliability and performance of the devices.

The method of the invention for fabricating a hybrid isolation structure including a LOCOS isolation and an STI first provides a semiconductor substrate consisting of a logic device region and a memory device region. The method of the invention then forms a pad oxide layer and a silicon nitride layer on the substrate in sequence. By performing a first photolithography and etching process on the silicon nitride layer, a pattern including a first opening located within the logic device region is formed on the silicon nitride layer. An etching process is then performed with both the patterned silicon nitride layer and the above photoresist layer still in-place serving as a mask, to remove a portion of the pad oxide layer and the substrate underneath to form a trench in the substrate. A plug of isolating material is formed within the trench. By performing a second photolithograph and etching process, a second pattern that includes a second opening is formed on the silicon nitride layer, wherein the second opening is located within the memory device region. A field oxide layer is formed within the second opening by performing a thermal oxidation process by using the re-patterned silicon nitride layer as a mask. Alter removing the silicon nitride layer from the substrate a hybrid isolation structure consisting of a LOCOS isolation and an STI is then formed in the substrate. Specifically, the LOCOS isolation is located within the memory device region and the STI is formed within the logic device region, wherein the STI is formed before the formation of the LOCOS isolation.

Additionally the invention also provides second method of for fabricating a hybrid isolation structure including a LOCOS isolation and an STI that starts with providing a semiconductor substrate consisting of a logic device region and a memory device region. The second method of the invention then forms a pad oxide layer and a silicon nitride layer on the substrate in sequence. By performing a first photolithography and etching process on the silicon nitride layer a pattern including a first opening located within the memory device region is formed on the silicon nitride layer. A field oxide layer is formed in the substrate within the first opening by performing a thermal oxidation process that uses the patterned silicon nitride layer as a mask. By performing a second photolithography and etching process, a second pattern that includes a second opening is formed on the silicon nitride layer, wherein the second opening is located within the logic device region. An etching process is then performed with both the re-patterned silicon nitride layer and the above photoresist layer still in-place serving as a mask to remove a portion of the pad oxide layer and the substrate underneath to form a trench in the substrate within the logic device region. A plug of isolating material is then formed within the trench. After removing the silicon nitride layer from the substrate a hybrid isolation structure consisting of a LOCOS isolation and an STI is then formed in the substrate. Specifically, the LOCOS isolation is located within the memory device region and the STI is formed within the logic device region, wherein the STI is formed after the formation of the LOCOS isolation.

### BRIEF DESCRIPTION OF DRAWINGS

The invention can be more fully understood by reading the following detailed description of the preferred embodiments, with reference made to the accompanying drawings, wherein:

FIG. 1 is a schematic cross-sectional view showing a conventional shallow trench isolation formed in a substrate;

FIG. 2 is a schematic, cross-sectional view showing the hybrid isolation structure of the invention formed in a semiconductor substrate;

FIGS. 3A through 3G are schematic, cross-sectional views showing the fabrication process for a hybrid isolation structure of a preferred embodiment according to the invention; and

FIGS. 4A through 4G are schematic, cross-sectional views showing the fabrication process for a hybrid isolation structure of another preferred embodiment according to the invention.

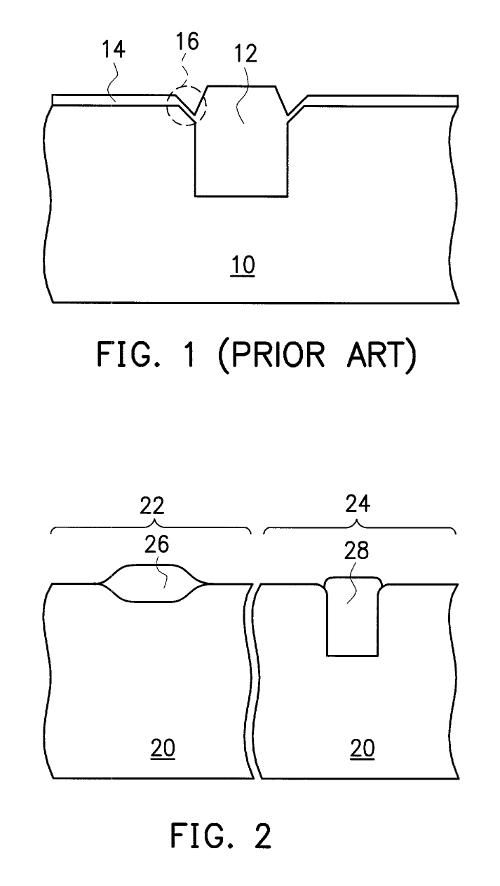

### DETAILED DESCRIPTION OF PREFERRED EMBODIMENTS

The invention provides a method for fabricating a hybrid isolation structure including a local oxidation of silicon (LOCOS) isolation and a shallow trench isolation (STI). The STI of the hybrid isolation structure of the invention is located within a device region, such as a logic region, that is operated at a low working voltage. The LOCOS isolation of the hybrid isolation structure of the invention is, on the other hand, located within a device region, such as a memory region, that is operated at a high working voltage. The method of the invention for fabricating a hybrid isolation structure can efficiently enhance the device density and ensure good performance and reliability at the same time.

FIG. 2 is a schematic, cross-sectional view of the hybrid isolation structure made with the method of the invention. The hybrid isolation structure of the invention includes a LOCOS isolation 26 and an STI 28, both formed on a substrate 20 such as a semiconductor substrate. The STI 28 of the hybrid isolation structure of the invention is located within a device region that is operated at a low working voltage, such as a logic region 24. The LOCOS isolation 26 of the hybrid isolation structure of the invention is, on the other hand, located within a device region that is operated at a high working voltage, such as a memory region 22. The operating voltage density within the logic device region is normally less than 5 MV/cm, but the voltage density within a memory device region is usually higher than 10 MV/cm. Therefore, in the consideration of both the reliability and integration of a semiconductor device, the invention provides a method to form an STI within the logic device region to enhance the integration of the device, and to form a LOCOS isolation within the memory device region to ensure the reliability of the device.

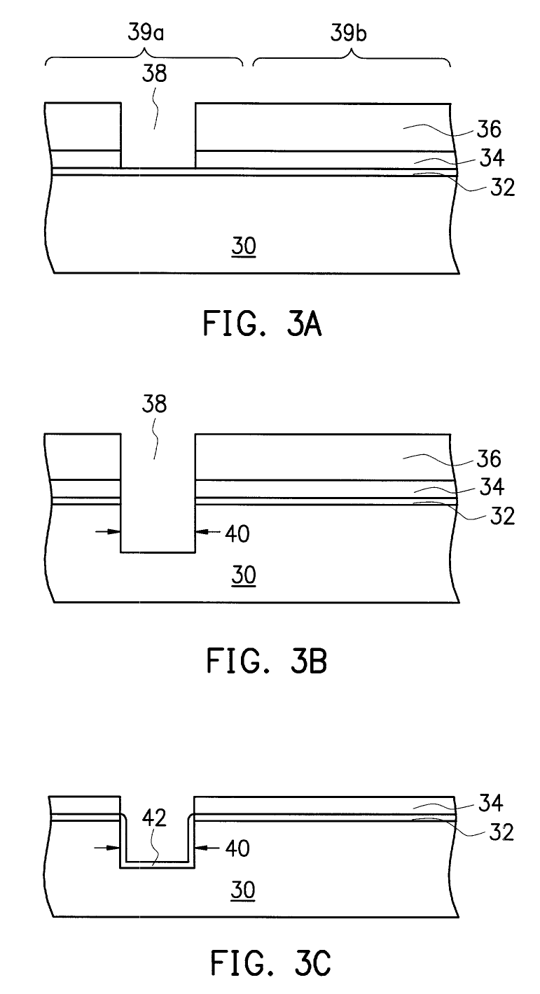

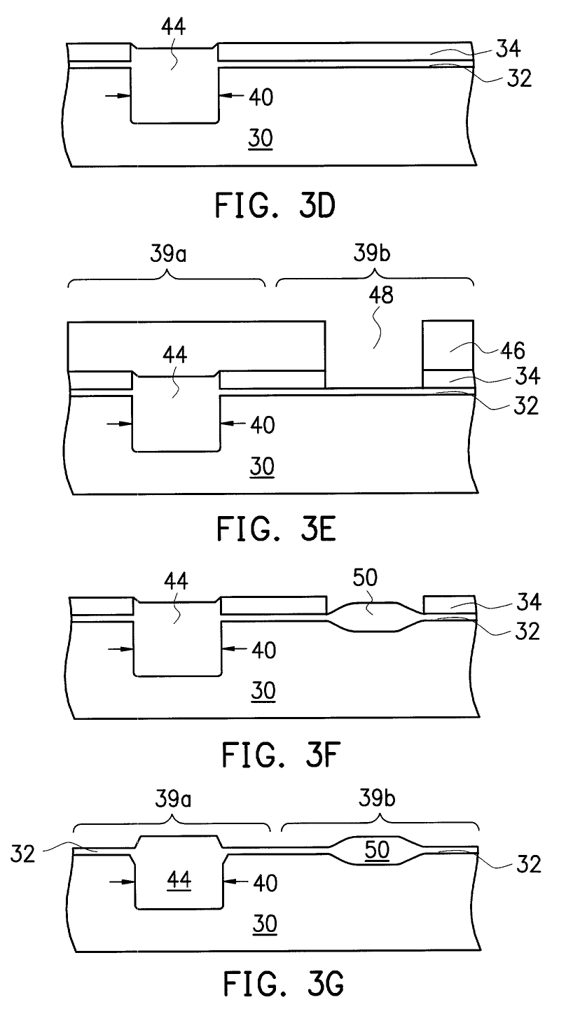

FIGS. 3A through 3G are schematic, cross-sectional views showing the fabrication process of a hybrid isolation structure made with the method of the invention.

Referring to FIG. 3A, a pad oxide layer 32 and a first insulating layer 34, preferably silicon nitride, are formed on a semiconductor substrate 30 in sequence, wherein the substrate 30) includes a logic device region 39a and a memory device region 39b. The preferred thickness of the first insulating layer 34 is about 500 to 2000 Å. If silicon nitride is used as material of the first insulating layer 34, it is preferable to form the silicon nitride layer with a chemical vapor deposition (CVD) process. By performing a first photolithography and etching process on the first insulating layer 34, a pattern including an opening 38 located within the logic device region 39a in transferred onto the insulating layer 34.

Then, as shown in FIG. 3B, a portion of the pad oxide layer 32 and the substrate 30 is removed to from a trench 40 in the substrate by performing an etching process with both the patterned first insulating layer 34 and the photoresist layer 36 serving as a mask.

Referring to FIG. 3C, a lining oxide 42 conformal to the trench 40 is formed by performing a thermal oxidation process. As shown in FIG. 3D, a plug 44 made of insulating material is formed in the trench 40. The formation of the plug 44 includes performing a CVD process to form a second insulating layer, preferably silicon oxide, on the first insulating layer 34 and fill the trench 40, and removing part of the second insulating layer from the top of the first insulating layer 34. The process that removes a portion of the second insulating layer form the top of the first insulating layer 34 is preferably a chemical mechanical polishing (CMP) process or an etching back process.

Referring to FIG. 3E, the first insulating layer 34 is re-patterned with another pattern including another opening 48 by performing a second photolithography and etching process. The opening 48 is located within the memory device region 39b. Then, by using the re-patterned first insulating layer 34 as a mask, a thermal oxidation process is performed to form a field oxide layer 50 in the substrate 30 within the opening 48, as shown in FIG. 3F. Referring next to FIG. 3G, the first insulating layer 34 is removed to finish the formation of the hybrid isolation structure of the invention. The STI 44 of the hybrid isolation structure is located within the logic region 39a, which is operated at a low working voltage. The LOCOS isolation 50 of the hybrid isolation structure is, on the other hand, located within the memory region 39b, which is operated at a high working voltage. The LOCOS isolation 50 is formed alter the formation of the STI 44.

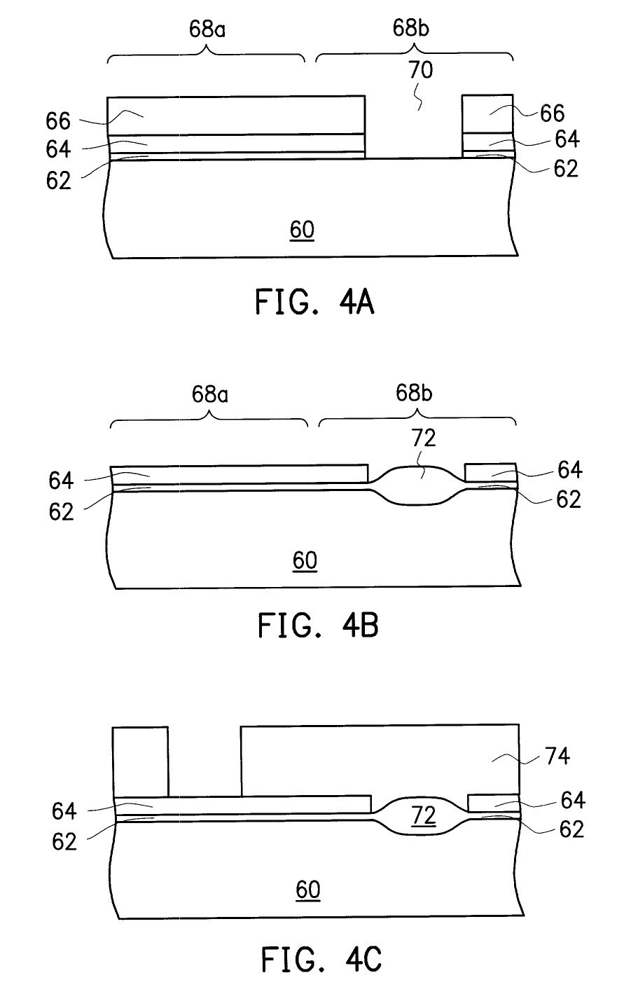

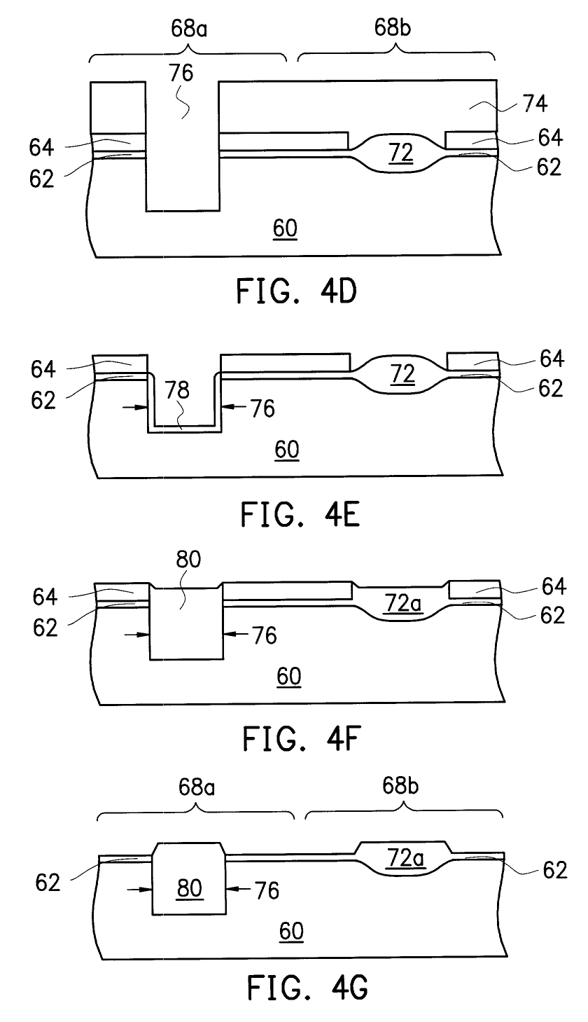

FIGS. 4A through 4G are schematic, cross-sectional views showing the fabrication process of a hybrid isolation structure made according to another method of the invention.

Referring to FIG. 4A, a pad oxide layer 62 and a first insulating layer 64, preferably silicon nitride, are formed on a semiconductor substrate 60 in sequence, wherein the substrate 60 includes a logic device region 68a and a memory device region 68b. The preferred thickness of the first insulating layer 64 is about 500 to 2000 Å. If silicon nitride is used as material of the first insulating layer 34, it is preferable to form the silicon nitride layer with a CVD process. By performing a first photolithography and etching process on the first insulating layer 64, a pattern including an opening 70 located within the memory device region 68b is transferred onto the insulating layer 64. Then, as shown in FIG. 4B, by using the patterned first insulating layer 64 as a mask, a thermal oxidation process is performed to form a field oxide layer 72 in the substrate 60 within the opening 70.

Referring to FIG. 4C, the first insulating layer 64 is re-patterned with another pattern by performing a second photolithography and etching process. A photoresist layer 74 is formed on the first insulating layer 64. An opening located within the logic device region 68a is formed in the photoresist layer 74. Referring to FIG. 4D, a portion of the pad oxide layer 62 and the substrate 60 are removed to form a trench 76 located within the logic device region 68a in the substrate 60 by performing an etching process with both the re-patterned first insulating layer 64 and the photoresist layer 74 serving as a mask.

Referring to FIG. 4E, a lining oxide 78 conformal to the trench 76 is formed by performing a thermal oxidation process. Then, as shown in FIG. 4F, a plug 80 made of insulating material is formed in the trench 60. The formation of the plug 80 includes performing a CVD process to form a second insulating layer, preferably silicon oxide, on the first insulating layer 64 and fill the trench 60, and removing part of the second insulating layer from the top of the first insulating layer 64. The process that removes a portion of the second insulating, laser from the top of the first insulating layer 64 is preferably a CMP process or an etching back process. While the process that removes a portion of the second insulating material from the top of the first insulating layer 64 is performed the top of the LOCOS isolation 72 is also planarized. The planarized LOCOS isolation 72a is still capable of providing sufficient isolation for isolating memory device regions.

Referring next to FIG. 4G, the first insulating layer 64 is removed to finish the formation of the hybrid isolation structure of the invention. The STI 80 of the hybrid isolation structure is located within the logic region 68a that is operated at a low working voltage. The LOCOS isolation 72a of the hybrid isolation structure is, on the other hand, located within the memory region 68b that is operated at a high working voltage. The LOCOS isolation 72a is formed before the formation of the STI 80.

According to the foregoing, the method of the invention forms a hybrid isolation structure that includes a LOCOS isolation in a high-voltage device region and an STI in a low-voltage device region. For some semiconductor devices such as embedded flash products, which contain both logic devices and memory devices, the method of the invention is capable of providing a solution by forming a hybrid isolation structure to enhance the integration of the device and ensure the reliability of the device, as well. The invention also pros ides alternative methods for fabricating a hybrid isolation structure; either one can be used in an existing fabrication process to achieve the same goal in accordance with the actual design and the existing fabricating process.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a hybrid isolation structure on a semiconductor substrate, wherein the semiconductor substrate consists of a logic device region and a memory device region, the method comprising steps of:
forming a pad oxide layer on the semiconductor substrate;
forming a first insulating layer on the pad oxide layer;
patterning the first insulating layer to form a first opening located within the logic device region;
removing a portion of the pad oxide layer exposed by the first opening and a portion of the semiconductor substrate underneath the first opening to form a trench in the semiconductor substrate;
filling the trench and the first opening with a second insulating layer to form a shallow trench isolation within the trench;
patterning the first insulating layer to form a second opening located within the memory device region;
forming a field oxide layer on the semiconductor substrate within the second opening; and
removing the first insulating layer.

2. The method of claim 1, further comprising a step of performing a thermal oxidation process to form a lining oxide layer within the trench before the step of filling the trench and the first opening with a second insulating layer, wherein the lining oxide layer is conformal to the trench.

3. The method of claim 1, wherein the first insulating layer is silicon nitride.

4. The method of claim 1, wherein the step of filling the trench and the first opening with a second insulating layer further comprises:
forming the second insulating layer on the first insulating layer to fill the trench and the first opening; and
removing a portion of the second insulating layer that covers the first insulating layer.

5. The method of claim 4, wherein the second insulating layer is silicon oxide.

6. The method of claim 4, wherein the step of forming the second insulating layer on the first insulating layer to fill the trench and the first opening includes chemical vapor deposition.

7. The method of claim 4, wherein the step of removing a portion of the second insulating layer that covers the first insulating layer includes chemical mechanical polishing.

8. The method of claim 1, wherein the step of forming a field oxide layer on the semiconductor substrate within the second opening includes thermal oxidation.

9. A method for fabricating a hybrid isolation structure on a semiconductor substrate, wherein the semiconductor substrate consists of a logic device region and a memory device region, the method comprising steps of:
forming a pad oxide layer on the semiconductor substrate;
forming a first insulating layer on the pad oxide layer;
patterning the first insulating layer to form a first opening located within the memory device region;
forming a field oxide layer on the semiconductor substrate within the first opening;
patterning the first insulating layer to form a second opening located within the memory device region;
removing a portion of the pad oxide layer exposed by the second opening and a portion of the semiconductor substrate underneath the second opening to form a trench in the semiconductor substrate;
filling the trench and the second opening with a second insulating layer to form a shallow trench isolation within the trench; and
removing the first insulating layer.

10. The method of claim 9, further comprising a step of performing a thermal oxidation process to form a lining oxide layer within the trench before the step of filling the trench and the second opening with a second insulating layer, wherein the lining oxide layer is conformal to the trench.

11. The method of claim 9, wherein the first insulating layer is silicon nitride.

12. The method of claim 9, wherein the step of filling the trench and the second opening with a second insulating layer further comprises:
forming the second insulating layer on the first insulating layer to fill the trench and the second opening; and
removing a portion of the second insulating layer that covers the first insulating layer.

13. The method of claim 12, wherein the second insulating layer is silicon oxide.

14. The method of claim 12, wherein the step of forming the second insulating layer on the first insulating layer to fill the trench and the second opening includes chemical vapor deposition.

15. The method of claim 12, wherein the step of removing a portion of the second insulating layer that covers the first insulating layer includes chemical mechanical polishing.

16. The method of claim 9, wherein the step of forming a field oxide layer on the semiconductor substrate within the first opening includes thermal oxidation.
